(19) United States
(12) Patent Application Publication
(10) Pub. No.: US 2025/0267847 A1
(43) Pub. Date: Aug. 21, 2025

(54) SEMICONDUCTOR DEVICE

(71) Applicant: Samsung Electronics Co., Ltd., Suwon-si (KR)

(72) Inventors: TAEJIN PARK, Suwon-si (KR); Sangsuk HAN, Suwon-si (KR); Sungjoo KANG, Suwon-si (KR); Keunui KIM, Suwon-si (KR); EuiJoong SHIN, Suwon-si (KR); HYEON-KYU LEE, Suwon-si (KR); HYERAN LEE, Suwon-si (KR); Hosang LEE, Suwon-si (KR); SEONGEUN CHO, Suwon-si (KR)

(21) Appl. No.: 19/050,728

(22) Filed: Feb. 11, 2025

(30) Foreign Application Priority Data
Feb. 16, 2024 (KR) 10-2024-0022750

(51) Int. Cl. H10B 12/00

(52) U.S. Cl. CPC H10B 12/315; H10B 12/05

(57) ABSTRACT

A semiconductor device may include a bit line structure, a gate insulating layer on the bit line structure, a first word line and a second word line respectively on first and second inner side surfaces of the gate insulating layer, a first channel layer and a second channel layer respectively in contact with first and second outer side surfaces of the gate insulating layer, a mask pattern in contact with the first and second word lines, and a mold layer in contact with a top surface of the mask pattern. The mask pattern may include an insulating material, and a level of the top surface of the mask pattern may be equal to or lower than a level of the uppermost portion of the first word line and a level of the uppermost portion of the second word line.

### CROSS-REFERENCE TO RELATED APPLICATIONS

This U.S. non-provisional patent application claims priority under 35 U.S.C. § 119 to Korean Patent Application No. 10-2024-0022750, filed on Feb. 16, 2024, in the Korean Intellectual Property Office, the entire contents of which are hereby incorporated by reference.

### BACKGROUND OF THE INVENTION

The present disclosure relates to a semiconductor device, and in particular, to a semiconductor device including a mask pattern.

As semiconductor devices are scaled down, fabrication technology should be developed that is capable of increasing integration density, operation speed, and production yield. Thus, semiconductor devices with vertical channel transistors have been suggested to increase an integration density of a semiconductor device and improve the resistance characteristics and current driving ability of the transistor.

### SUMMARY

An embodiment of the inventive concept provides a semiconductor device with improved electrical characteristics and reliability.

According to an embodiment of the inventive concept, a semiconductor device may include a bit line structure, a gate insulating layer on the bit line structure, a first word line and a second word line respectively on first and second inner side surfaces of the gate insulating layer, a first channel layer and a second channel layer respectively in contact with first and second outer side surfaces of the gate insulating layer, a mask pattern in contact with the first and second word lines, and a mold layer in contact with a top surface of the mask pattern. The mask pattern may include an insulating material, and a level of the top surface of the mask pattern may be equal to or lower than a level of the uppermost portion of the first word line and a level of the uppermost portion of the second word line.

According to an embodiment of the inventive concept, a semiconductor device may include a bit line structure, a gate insulating layer on the bit line structure, a first word line and a second word line respectively on first and second inner side surfaces of the gate insulating layer, a first channel layer and a second channel layer respectively on first and second outer side surfaces of the gate insulating layer, a mask pattern between the first and second word lines, and a mold layer in contact with a top surface of the mask pattern. Each of the first and second word lines may include an outer side surface in contact with the gate insulating layer and an inner side surface opposite to the outer side surface. The mask pattern may include an insulating material, and a level of a top surface of the first channel layer may be higher than a level of a top surface of the mask pattern.

According to an embodiment of the inventive concept, a semiconductor device may include a bit line structure, a gate structure on the bit line structure, a first channel layer and a second channel layer spaced apart from each other with the gate structure interposed therebetween, landing pads on the first and second channel layers, and data storage patterns connected to the landing pads. The gate structure may include a gate insulating layer on the bit line, a first word line and a second word line on the gate insulating layer, a mask pattern between the first and second word lines, and a mold layer in contact with a top surface of the mask pattern. The mask pattern and the mold layer may be formed of insulating materials that are different from each other, and a level of the top surface of the mask pattern may be lower than a level of the uppermost portion of the first word line.

### BRIEF DESCRIPTION OF THE DRAWINGS

FIG. 1 is a block diagram illustrating a semiconductor device according to an embodiment of the inventive concept.

FIGS. 2 and 3 are perspective views schematically illustrating a semiconductor device according to an embodiment of the inventive concept.

FIG. 4 is a plan view illustrating a semiconductor device according to an embodiment of the inventive concept.

FIG. 5 is a sectional view taken along a line A-A′ of FIG. 4.

FIG. 6 is a sectional view taken along a line B-B′ of FIG. 4.

FIG. 7 is a sectional view taken along a line C-C′ of FIG. 4.

FIG. 8 is an enlarged sectional view illustrating a portion ‘E’ of FIG. 5.

FIGS. 9A, 9B, and 9C are sectional views illustrating a method of fabricating a semiconductor device, according to an embodiment of the inventive concept.

FIG. 10 is a sectional view illustrating a semiconductor device according to an embodiment of the inventive concept.

FIG. 11 is a sectional view illustrating a semiconductor device according to an embodiment of the inventive concept.

FIG. 12 is a sectional view illustrating a semiconductor device according to an embodiment of the inventive concept.

FIG. 13 is a sectional view illustrating a semiconductor device according to an embodiment of the inventive concept.

### DETAILED DESCRIPTION

Example embodiments of the inventive concepts will now be described more fully with reference to the accompanying drawings, in which example embodiments are shown.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

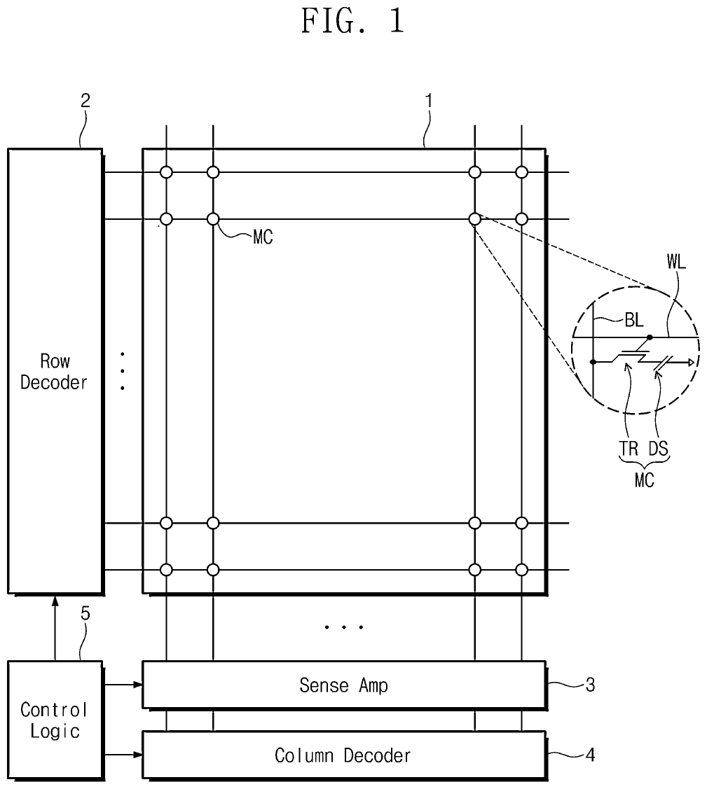

FIG. 1 is a block diagram illustrating a semiconductor device according to an embodiment of the inventive concept.

Referring to FIG. 1, the semiconductor device may include a memory cell array 1, a row decoder 2, a sense amplifier 3, a column decoder 4, and a control logic circuit 5.

The memory cell array 1 may include a plurality of memory cells MC, which are two- or three-dimensionally arranged. Each of the memory cells MC may be provided between and connected to a word line WL and a bit line BL, which are provided to cross each other.

Each of the memory cells MC may include a selection element TR and a data storage device DS. The selection element TR and the data storage device DS may be electrically connected to each other. The selection element TR may be connected to both the word line WL and the bit line BL. In other words, the selection element TR may be provided at an intersection of the word and bit lines WL and BL.

The selection element TR may be a field effect transistor. The data storage device DS may be a capacitor, a magnetic tunnel junction pattern, or a variable resistor. As an example, the selection element TR may be a transistor whose gate, source, and drain terminals are connected to the word line WL, the bit line BL, and the data storage device DS, respectively.

The row decoder 2 may be configured to decode address information, which is input from the outside, and to select one of the word lines WL of the memory cell array 1, based on the decoded address information. The address information decoded by the row decoder 2 (e.g., a row address) may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information (e.g., a column address) decoded by the column decoder 4, and a reference bit line.

The column decoder 4 may establish a data transmission path between the sense amplifier 3 and an external device (e.g., a memory controller). The column decoder 4 may be configured to decode address information, which is input from the outside, and to select one of the bit lines BL, based on the decoded address information.

The control logic circuit 5 may generate control signals, which are used to control an operation of writing or reading data to or from the memory cell array 1.

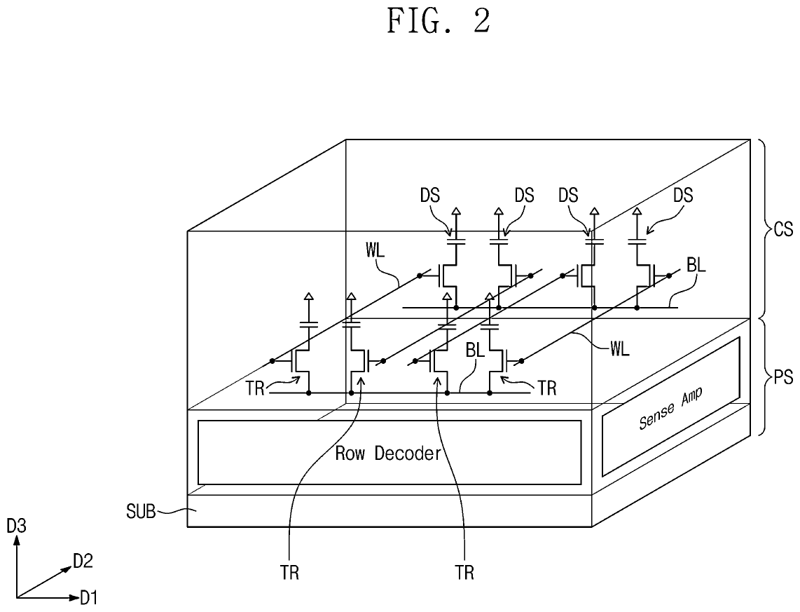

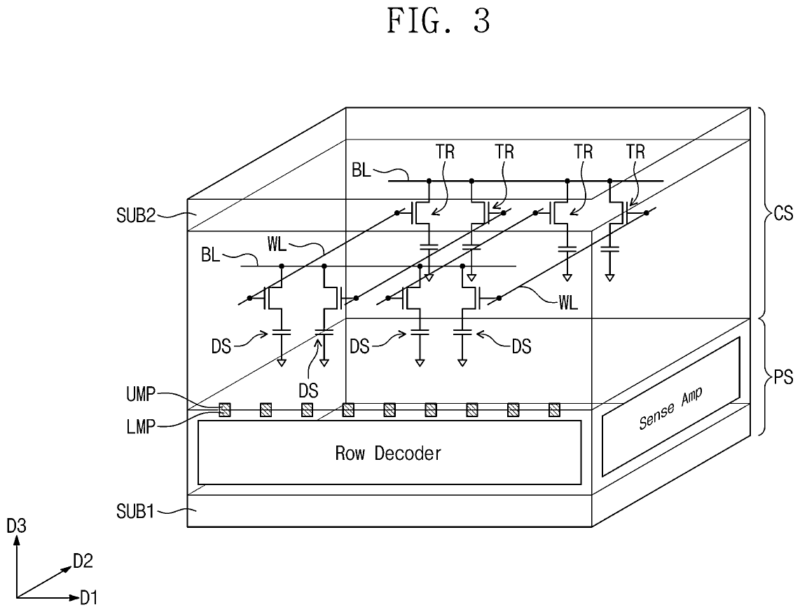

FIGS. 2 and 3 are perspective views schematically illustrating a semiconductor device according to an embodiment of the inventive concept.

Referring to FIGS. 2 and 3, the semiconductor device may include a peripheral circuit structure PS and a cell array structure CS, which is connected to the peripheral circuit structure PS.

The peripheral circuit structure PS may include core and peripheral circuits formed on a substrate SUB. The core and peripheral circuits may include the row and column decoders 2 and 4, sense amplifiers 3, and the control logic circuit 5 described with reference to FIG. 1.

The cell array structure CS may include a memory cell array (e.g., 1 of FIG. 1), in which memory cells (e.g., MC of FIG. 1) are two- or three-dimensionally arranged. Each of the memory cells MC may include a selection element TR and a data storage device DS, as described above.

In an embodiment, the selection element TR of each of the memory cells (e.g., MC of FIG. 1) may be a vertical channel transistor (VCT). The vertical channel transistor may be configured to have a channel region whose lengthwise direction is substantially normal to a top surface of the substrate SUB. The data storage device DS of each of the memory cells MC of FIG. 1 may be a capacitor.

In the embodiment of FIG. 2, the peripheral circuit structure PS may be provided on the substrate SUB, and the cell array structure CS may be provided on the peripheral circuit structure PS.

In the embodiment of FIG. 3, the peripheral circuit structure PS may be provided on a first substrate SUB1, and the cell array structure CS may be provided on a second substrate SUB2. The first and second substrates SUB1 and SUB2 may face each other.

First metal pads LMP may be provided in the uppermost portion of the peripheral circuit structure PS. The first metal pads LMP may be electrically connected to the core and peripheral circuits 2, 3, 4, and 5 of FIG. 1.

Second metal pads UMP may be provided in the lowermost portion of the cell array structure CS. The second metal pads UMP may be electrically connected to the memory cell array 1 of FIG. 1. The second metal pads UMP may be directly bonded to (i.e., in contact with and merged with) the first metal pads LMP of the peripheral circuit structure PS.

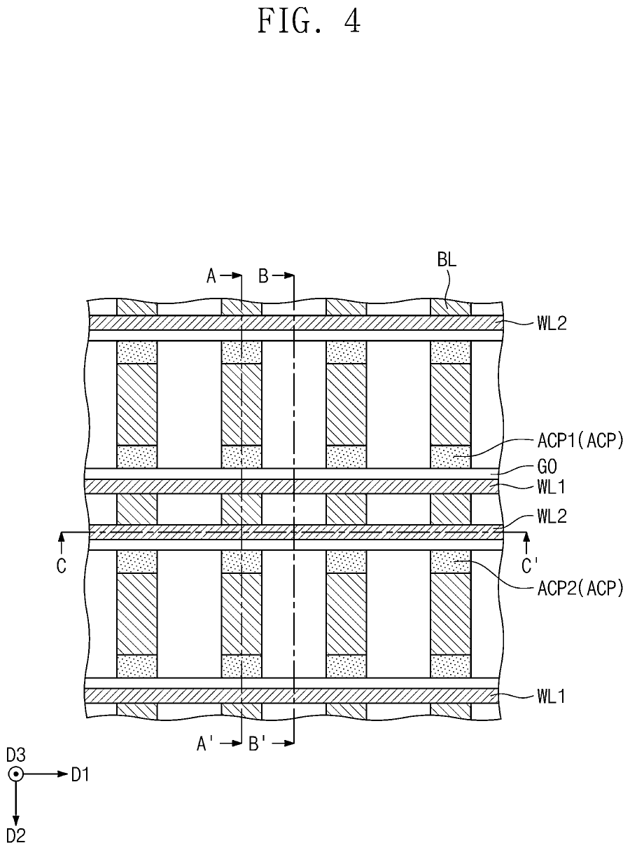

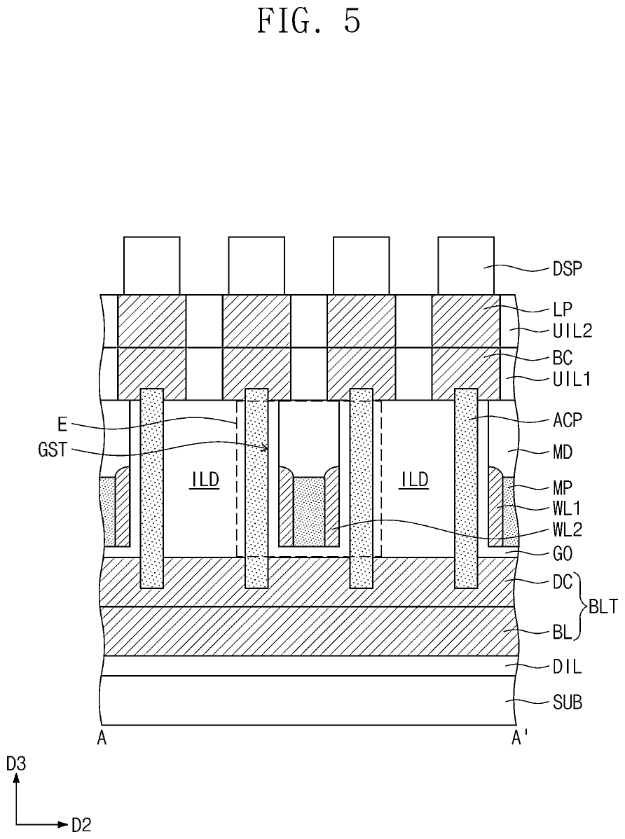

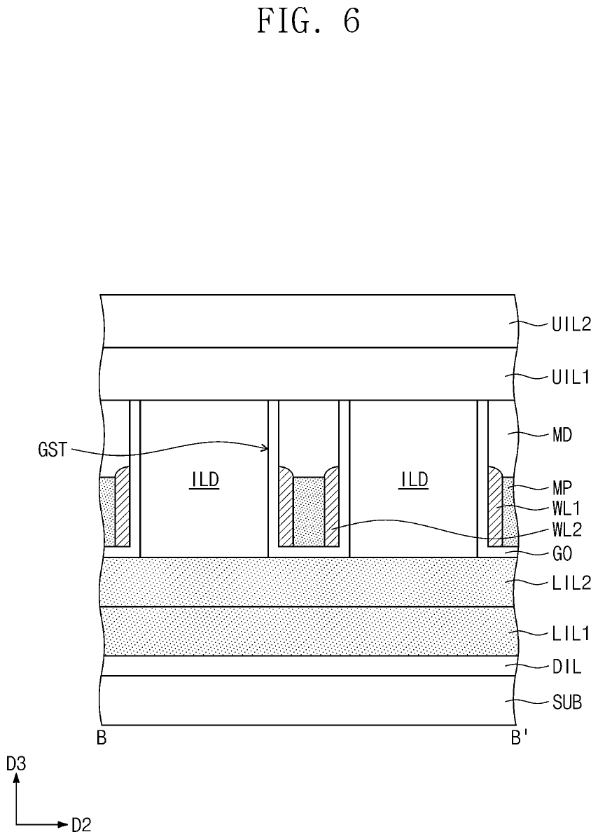

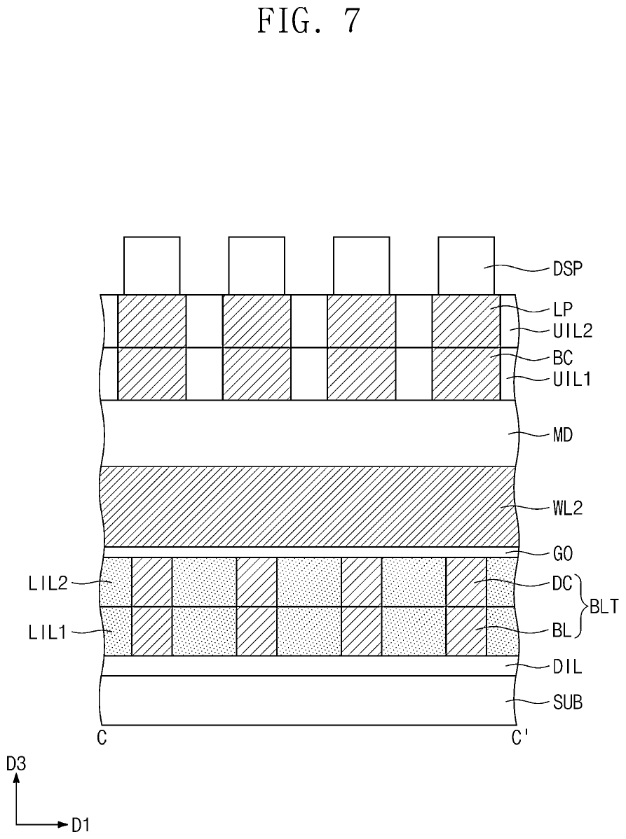

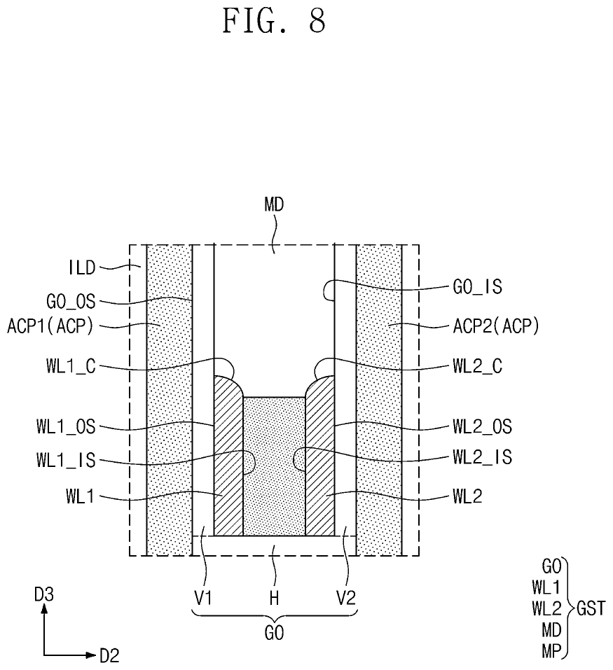

FIG. 4 is a plan view illustrating a semiconductor device according to an embodiment of the inventive concept. FIG. 5 is a sectional view taken along a line A-A′ of FIG. 4. FIG. 6 is a sectional view taken along a line B-B′ of FIG. 4. FIG. 7 is a sectional view taken along a line C-C′ of FIG. 4. FIG. 8 is an enlarged sectional view illustrating a portion ‘E’ of FIG. 5.

Referring to FIGS. 4 to 8, an interlayer insulating layer DIL may be provided on the substrate SUB. The substrate SUB may be a plate-shaped structure that is extended parallel to a plane defined by a first direction D1 and a second direction D2. The first and second directions D1 and D2 may not be parallel to each other. For ease of description, the first and second directions D1 and D2 may be considered horizontal directions, and may be orthogonal to each other. Directional terms use herein, such as “horizontal,” “vertical,” “beneath,” “below,” “lower,” “above,” “upper,” “top,” “bottom,” “front,” “rear,” and the like, may be used herein for ease of description to describe positional relationships, such as illustrated in the figures, for example. However, it will be understood that these directional terms are used to help clearly convey positional relationships and encompass different orientations of the device in addition to the orientation depicted in the figures. The interlayer insulating layer DIL may include an insulating material.

In an embodiment, the peripheral circuit structure PS described with reference to FIG. 2 may be provided between the substrate SUB and the interlayer insulating layer DIL. In an embodiment, an integrated circuit (e.g., a logic device) may be provided between the substrate SUB and the interlayer insulating layer DIL.

A first lower insulating layer LIL1 may be provided on the interlayer insulating layer DIL. A second lower insulating layer LIL2 may be provided on the first lower insulating layer LIL1. The first and second lower insulating layers LIL1 and LIL2 may include an insulating material. The first and second lower insulating layers LIL1 and LIL2 may be a multi-layered structure including a plurality of component insulating layers. In an embodiment, the first and second lower insulating layers LIL1 and LIL2 may be formed of at least one of nitride or oxide materials.

A bit line structure BLT may be provided in the first and second lower insulating layers LIL1 and LIL2. The bit line structure BLT may be disposed on the interlayer insulating layer DIL. The bit line structure BLT may include bit lines BL and connection layers DC.

A plurality of bit lines BL may be provided in the first lower insulating layer LIL1. Each of the bit lines BL may extend in the second direction D2. The bit lines BL may be arranged side by side in the first direction D1. The bit lines BL may be spaced apart from each other in the first direction D1.

The bit line BL may include a conductive material. For example, the bit line BL may be formed of and/or include at least one of doped semiconductor materials (e.g., doped silicon and doped germanium), conductive metal nitride materials (e.g., titanium nitride and tantalum nitride), metallic materials (e.g., tungsten, titanium, and tantalum), and metal-semiconductor compounds (e.g., tungsten silicide, cobalt silicide, and titanium silicide). The bit line BL may be a single conductive layer (e.g., be a single continuous homogenous layer (formed of the same base material throughout)) or a conductive layer having multiple component layers.

A plurality of connection layers DC may be provided in the second lower insulating layer LIL2. Each connection layer DC may be disposed on a corresponding bit line BL. Each of the connection layers DC may extend in the second direction D2. The connection layers DC may be arranged side by side in the first direction D1. The connection layers DC may be spaced apart from each other in the first direction D1. The connection layers DC may include a conductive material. As an example, the connection layers DC may include doped silicon. Each of the connection layers DC may have the same horizontal shape and size of the bit line BL to which it is in contact with. It should be appreciated that a pair of a bit line BL and its corresponding connection layer DC may itself be considered a bit line (i.e., one formed of multiple conductive components).

Channel layers ACP may be provided on the connection layers DC. A plurality of channel layers ACP may be in contact with each of the connection layers DC. The channel layers ACP may be connected to the bit line BL through the connection layers DC. The channel layers ACP, which are provided on each of the connection layers DC, may be arranged in the second direction D2. The channel layers ACP may extend in a third direction D3. The third direction D3 may not be parallel to the first and second directions D1 and D2. In an embodiment, the third direction D3 may be a vertical direction that is orthogonal to the first and second directions D1 and D2. The channel layers ACP may include a semiconductor material. As an example, the channel layers ACP may include doped silicon.

In an embodiment, the channel layers ACP may include at least one of oxide semiconductor materials (e.g., InGaZnO, InGaSiO, InSnZnO, InZnO, ZnO, ZnSnO, ZnON, ZrZnSnO, SnO, HfInZnO, GaZnSnO, AlZnSnO, YbGaZnO, and InGaO), but the inventive concept is not limited to this example. As an example, the channel layers ACP may be formed of or include indium gallium zinc oxide (IGZO). The channel layers ACP may have a single- or multi-layered structure of the oxide semiconductor material. The channel layers ACP may be formed of or include an amorphous, single-crystalline, or poly-crystalline oxide semiconductor material. In an embodiment, the channel layers ACP may have a band gap energy that is greater than that of silicon. For example, the channel layers ACP may have a band gap energy of about 1.5 eV to 5.6 eV. In an embodiment, when the channel layers ACP have a band gap energy of about 2.0 eV to 4.0 eV, the channel layers ACP may have an optimized channel performance. For example, the channel layers ACP may have a polycrystalline or amorphous structure, but the inventive concept is not limited to this example. In an embodiment, the channel layers ACP may be or include a two-dimensional semiconductor material (e.g., a 2D material of a single layer of atoms, such as graphene, carbon nanotube, or combinations thereof).

The channel layers ACP may include first channel layers ACP1 and second channel layers ACP2. The first and second channel layers ACP1 and ACP2 may be alternately disposed.

Gate structures GST may be provided on the connection layers DC and the second lower insulating layer LIL2. Each of the gate structures GST may extend in the first direction D1. The gate structures GST may be arranged side by side in the second direction D2. The first and second channel layers ACP1 and ACP2, which are adjacent to each other in the second direction D2, may be spaced apart from each other with a corresponding gate structure GST interposed therebetween. The gate structure GST may be in contact with the first and second channel layers ACP1 and ACP2, which are adjacent to each other in the second direction D2.

The gate structure GST may include a gate insulating layer GO, a first word line WL1, a second word line WL2, a mask pattern MP, and a mold layer MD. The gate insulating layer GO, the first word line WL1, the second word line WL2, the mask pattern MP, and the mold layer MD, which are included in each of the gate structures GST, may be provided between the first and second channel layers ACP1 and ACP2, which are adjacent to each other in the second direction D2. It should be appreciated that the drawings show multiple first word lines WL1 and multiple second word lines WL2 and all of these word lines be different word lines from one another (e.g., the plurality of first word lines WL1 may electrical nodes that are different from one another and, as well, the plurality of second word lines WL1 may electrical nodes that are different from one another).

The gate insulating layer GO may be provided on the connection layer DC of the bit line structure BLT. The gate insulating layer GO may extend in the first direction D1. The gate insulating layer GO may include an insulating material. As an example, the gate insulating layer GO may include an oxide material.

An outer side surface GO_OS of the gate insulating layer GO may be in contact with the first channel layer ACP1 or the second channel layer ACP2. An inner side surface GO_IS of the gate insulating layer GO may be in contact with the first word line WL1 or the second word line WL2. The inner side surface GO_IS of the gate insulating layer GO may be in contact with the mold layer MD.

In an embodiment, the gate insulating layer GO may be formed of or include at least one of silicon oxide, silicon oxynitride, or high-k dielectric materials whose dielectric constants are higher than that of silicon oxide. The high-k dielectric material may include metal oxide materials or metal oxynitride materials. For example, the high-k dielectric material for the gate insulating layer GO may include at least one of HfO₂, HfSiO, HfSiON, HfTaO, HfTiO, HfZrO, ZrO₂, or Al₂O₃, but the inventive concept is not limited to this example.

The gate insulating layer GO may include a first vertical portion V1, a second vertical portion V2, and a horizontal portion H. The first vertical portion V1 of the gate insulating layer GO may extend in the third direction D3. The first vertical portion V1 may be disposed between the first channel layer ACP1 and the first word line WL1. The first vertical portion V1 may be in contact with the first channel layer ACP1, the first word line WL1, and the mold layer MD. The second vertical portion V2 of the gate insulating layer GO may extend in the third direction D3. The second vertical portion V2 may be disposed between the second channel layer ACP2 and the second word line WL2. The second vertical portion V2 may be in contact with the second channel layer ACP2, the second word line WL2, and the mold layer MD. The first and second vertical portions V1 and V2 of the gate insulating layer GO may be spaced apart from each other in the second direction D2. The horizontal portion H of the gate insulating layer GO may connect the first and second vertical portions V1 and V2 of the gate insulating layer GO to each other. The horizontal portion H of the gate insulating layer GO may extend in the second direction D2. The horizontal portion H of the gate insulating layer GO may be in contact with a top surface of the connection layer DC of the bit line structure BLT.

The first and second word lines WL1 and WL2 may be provided on the gate insulating layer GO. Bottom surfaces of the first and second word lines WL1 and WL2 may be in contact with a top surface of the horizontal portion H of the gate insulating layer GO. The first and second word lines WL1 and WL2 may be spaced apart from each other in the second direction D2. The first and second word lines WL1 and WL2 may extend in the first direction D1.

The first and second word lines WL1 and WL2 may include a conductive material. The first and second word lines WL1 and WL2 may be formed of or include at least one of, for example, doped polysilicon, metallic materials (e.g., Al, Cu, Ti, Ta, Ru, W, Mo, Pt, Ni, Co), conductive metal nitride materials (e.g., TiN, TaN, WN, NbN, TiAlN, TiSiN, TaSiN, RuTiN), conductive metal silicide materials, or conductive metal oxide materials, but the inventive concept is not limited to this example. The first and second word lines WL1 and WL2 may be a single- or multi-layered structure formed of the afore-described materials. In an embodiment, the first and second word lines WL1 and WL2 may include a two-dimensional semiconductor material (e.g., graphene, carbon nanotube, or combinations thereof).

The first word line WL1 may include an inner side surface WL1_IS, an outer side surface WL1_OS, and a curved surface WL1_C. The second word line WL2 may include an inner side surface WL2_IS, an outer side surface WL2_OS, and a curved surface WL2_C. The inner side surface WL1_IS of the first word line WL1 and the inner side surface WL2_IS of the second word line WL2 may be provided to face each other. Side surfaces of the first and second word lines WL1 and WL2, which are adjacent to each other, may be the inner side surfaces WL1_IS and WL2_IS of the first and second word lines WL1 and WL2. The outer side surface WL1_OS of the first word line WL1 may be opposite to the inner side surface WL1_IS of the first word line WL1. The outer side surface WL1_OS of the first word line WL1 may be in contact with the first vertical portion V1 of the gate insulating layer GO. The outer side surface WL2_OS of the second word line WL2 may be opposite to the inner side surface WL2_IS of the second word line WL2. The outer side surface WL2_OS of the second word line WL2 may be in contact with the second vertical portion V2 of the gate insulating layer GO. The inner and outer side surfaces WL1_IS and WL1_OS of the first word line WL1 and the inner and outer side surfaces WL2_IS and WL2_OS of the second word line WL2 may extend in the first direction D1. The curved surface WL1_C of the first word line WL1 may connect the inner and outer side surfaces WL1_IS and WL1_OS of the first word line WL1 to each other. The curved surface WL2_C of the second word line WL2 may connect the inner and outer side surfaces WL2_IS and WL2_OS of the second word line WL2 to each other. The curved surface WL1_C of the first word line WL1 and the curved surface WL2_C of the second word line WL2 may have a curved shape.

The mask pattern MP may be provided between the first and second word lines WL1 and WL2. A bottom surface of the mask pattern MP may be in contact with the top surface of the horizontal portion H of the gate insulating layer GO. A side surface of the mask pattern MP may be in contact with the inner side surface WL1_IS of the first word line WL1 and the inner side surface WL2_IS of the second word line WL2.

The mold layer MD may be provided between the first and second vertical portions V1 and V2 of the gate insulating layer GO. The mold layer MD may be in contact with the first and second vertical portions V1 and V2 of the gate insulating layer GO, the curved surface WL1_C of the first word line WL1, the curved surface WL2_C of the second word line WL2, and the top surface of the mask pattern MP. The mold layer MD may include an insulating material. As an example, the mold layer MD may include an oxide material.

Insulating layers ILD may be provided. Each insulating layer ILD may be provided between a corresponding pair of adjacent gate structures GST. The insulating layers ILD may be in contact with the first and second channel layers ACP1 and ACP2, which are adjacent to each other. The insulating layers ILD may include an insulating material. As an example, the insulating layers ILD may include an oxide material.

Data contacts BC and landing pads LP may be provided on the channel layers ACP. Pairs of the data contacts BC and the landing pads LP may vertically overlap with a corresponding one of the channel layers ACP. The data contacts BC may be spaced apart from each other in the first or second direction D1 or D2 and/or arranged in a matrix shape. The landing pads LP may be spaced apart from each other in the first or second direction D1 or D2 or in a matrix shape. The data contacts BC may connect the channel layers ACP to the landing pads LP.

When viewed in a plan view, the landing pads LP may be spaced apart from each other in the first and second directions D1 and D2 and may be arranged in various ways (e.g., in matrix, zigzag, and honeycomb arrangement). When viewed in a plan view, each of the landing pads LP may have various shapes (e.g., circular, elliptical, rectangular, square, diamond, and hexagonal shapes).

The data contacts BC and the landing pads LP may include a conductive material. The data contacts BC and the landing pads LP may be formed of or include at least one of doped silicon, Al, Cu, Ti, Ta, Ru, W, Mo, Pt, Ni, Co, TiN, TaN, WN, NbM, TiAl, TiAlN, TiSi, TiSiN, TaSi, TaSiN, RuTiN, NiSi, CoSi, IrOx, RuOx, or combinations thereof, but the inventive concept is not limited to this example or a specific embodiment.

A first upper insulating layer UIL1 may be provided between the data contacts BC. The first upper insulating layer UIL1 may be provided on the gate structure GST. The first upper insulating layer UIL1 may separate the data contacts BC from each other.

A second upper insulating layer UIL2 may be provided between the landing pads LP. The second upper insulating layer UIL2 may be provided on the first upper insulating layer UIL1. The second upper insulating layer UIL2 may separate the landing pads LP from each other.

The first and second upper insulating layers UIL1 and UIL2 may include an insulating material. In an embodiment, the first and second upper insulating layers UIL1 and UIL2 may include an oxide material. In an embodiment, the first and second upper insulating layers UIL1 and UIL2 may be a multi-layered structure including a plurality of insulating layers.

Data storage patterns DSP may be provided on the landing pads LP, respectively. The data storage pattern DSP may be electrically connected to the channel layer ACP through the data contacts BC and the landing pads LP.

In an embodiment, each of the data storage patterns DSP may be a capacitor and may include bottom and top electrodes and a capacitor dielectric layer interposed therebetween. In this case, the bottom electrode may be in contact with the landing pad LP, and the bottom electrode may have various shapes (e.g., circular, elliptical, rectangular, square, diamond, hexagonal shapes), when viewed in a plan view.

In an embodiment, each of the data storage patterns DSP may be a variable resistance pattern whose resistance can be switched to one of at least two states by an electric pulse applied thereto. For example, the data storage pattern DSP may be formed of or include at least one of phase-change materials whose crystal state can be changed depending on an amount of a current applied thereto, perovskite compounds, transition metal oxides, magnetic materials, ferromagnetic materials, or antiferromagnetic materials.

The entire top surface of the horizontal portion H of the gate insulating layer GO may be covered with the bottom surface of the first word line WL1, the bottom surface of the second word line WL2, and the bottom surface of the mask pattern MP. The entire surface of the first word line WL1 may be covered with the gate insulating layer GO, the mask pattern MP, and the mold layer MD. The inner side surface WL1_IS of the first word line WL1 may be covered with the mask pattern MP. The entire surface of the second word line WL2 may be covered with the gate insulating layer GO, the mask pattern MP, and the mold layer MD. The inner side surface WL2_IS of the second word line WL2 may be covered with the mask pattern MP.

In an embodiment, according to an etch-back process, the mask pattern MP may have an etch selectivity of approximately 1 with respect to the first and second word lines WL1 and WL2, such that an etch rate of the mask pattern MP is substantially equal to an etch rate of the first and second word lines WL1 and WL2. For example, the mask pattern MP may have an etch selectivity of 0.95 to 1.05 with respect to the first and second word lines WL1 and WL2. The mask pattern MP may include an insulating material different from the mold layer MD. In an embodiment, the mask pattern MP may include a nitride material.

The top surface of the mask pattern MP may be even with or lower than the uppermost portion of the first word line WL1 and even with or lower than the uppermost portion of the second word line WL2. The top surface of the mask pattern MP may be lower than the top surface of the first channel layer ACP1 and the top surface of the second channel layer ACP2.

According to an embodiment of the inventive concept, the semiconductor device may include the mask pattern MP, which may have an etch selectivity of approximately 1 with respect to the first and second word lines WL1 and WL2 during an etch-back process (the mask pattern MP and the first and second word lines WL1 and WL2 may have substantially the same etch rate during an etch-back process). Since the mask pattern MP is provided, a space created using the etch-back process (which is subsequently filled with the mold layer MD) may be enlarged. Enlarging the space that is filled with the mold layer may reduce the possibility of a void or a seem being formed in a process of filling the mold layer MD, and thereby improve the electrical characteristics and reliability of the semiconductor device.

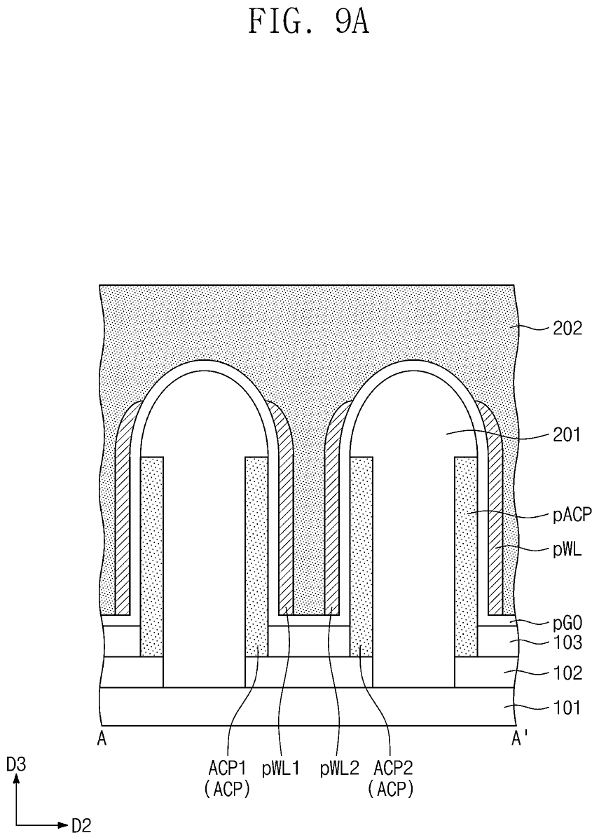

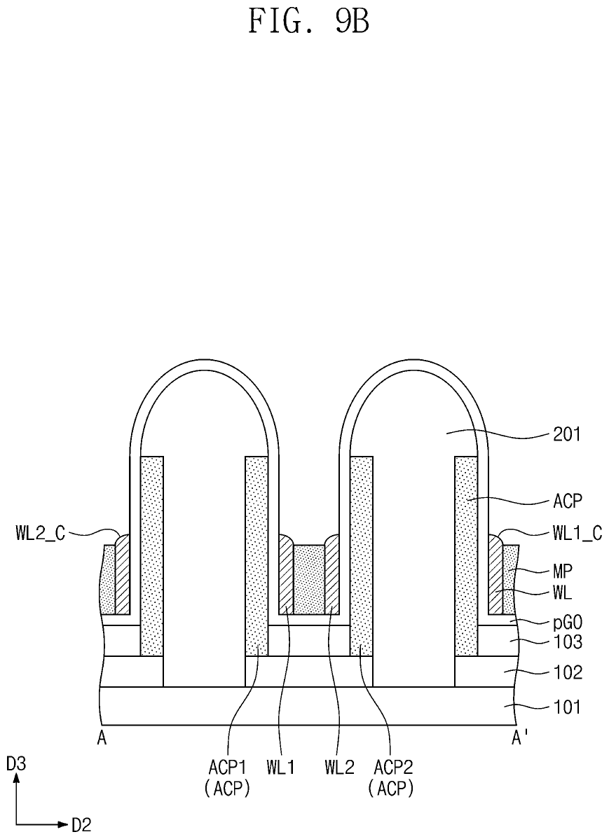

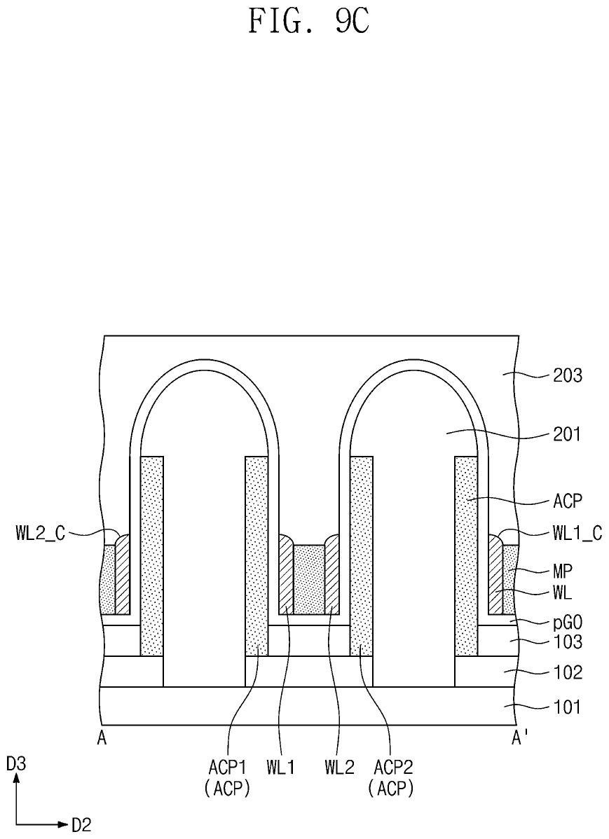

FIGS. 9A, 9B, and 9C are sectional views illustrating a method of fabricating a semiconductor device, according to an embodiment of the inventive concept. FIGS. 9A, 9B, and 9C may correspond to a portion of FIG. 5.

Referring to FIGS. 9A, 9B, and 9C, a wafer substrate 101, a first insulating layer 102 on the wafer substrate 101, and a second insulating layer 103 on the first insulating layer 102 may be formed. In an embodiment, the wafer substrate 101 may be a silicon-on-insulator (SOI) substrate or a germanium-on-insulator (GOI) substrate. In an embodiment, the wafer substrate 101 may be a crystalline semiconductor wafer (e.g., a bulk semiconductor wafer substrate) formed of or include at least one of silicon, germanium, silicon-germanium, gallium-phosphorus, or gallium-arsenic. The first and second insulating layers 102 and 103 may include an insulating material. In an embodiment, the first and second insulating layers 102 and 103 may include an oxide material.

The channel layers ACP and insulating structures 201 may be formed. The channel layers ACP may be formed on the first insulating layer 102. The second insulating layer 103 may cover a portion of a side surface of the channel layer ACP. The insulating structures 201 may be formed on the wafer substrate 101. The first insulating layer 102 may cover a portion of a side surface of the insulating structure 201. The insulating structure 201 may include an insulating material. As an example, the insulating structure 201 may include an oxide material.

In an embodiment, the formation of the channel layers ACP may include forming an upper substrate on the first insulating layer 102, forming a photoresist pattern on the upper substrate, and patterning the upper substrate using the photoresist patterns as an etch mask. The upper substrate may be patterned to form the channel layers ACP, which are spaced apart from each other.

A preliminary gate insulating layer pGO, a first preliminary word lines pWL1, a second preliminary word lines pWL2, and a mask insulating layer 202 may be formed. The preliminary gate insulating layer pGO may be formed on the second insulating layer 103, the channel layers ACP, and the insulating structures 201. The preliminary gate insulating layer pGO may be formed to conformally cover a top surface of the second insulating layer 103, side surfaces of the channel layers ACP, and top surfaces of the insulating structures 201. The first and second preliminary word lines pWL1 and pWL2 may be formed on the preliminary gate insulating layer pGO. The first and second preliminary word lines pWL1 and pWL2 may be alternately disposed. The first and second preliminary word lines pWL1 and pWL2 may be disposed to be spaced apart from each other in the second direction D2. The mask insulating layer 202 may be formed on the preliminary gate insulating layer pGO and the first and second preliminary word lines pWL1 and pWL2. The mask insulating layer 202 may be formed to fill a space between the first and second preliminary word lines pWL1 and pWL2.

Referring to FIG. 9B, a portion of the mask insulating layer 202, a portion of the first preliminary word line pWL1, and a portion of the second preliminary word line pWL2 may be removed. As a result of the removal process, a surface of the preliminary gate insulating layer pGO may be exposed to the outside. The portion of the mask insulating layer 202 may be removed to form the mask pattern MP. The top surface of the mask pattern MP may be exposed to the outside. The portion of the first preliminary word line pWL1 and the portion of the second preliminary word line pWL2 may be removed to form the first and second word lines WL1 and WL2. The curved surface WL1_C of the first word line WL1 and the curved surface WL2_C of the second word line WL2 may be exposed to the outside.

In an embodiment, the portion of the mask insulating layer 202, the portion of the first preliminary word line pWL1, and the portion of the second preliminary word line pWL2 may be removed by an etch-back process. According to the etch-back process, the mask insulating layer 202 and the first and second preliminary word lines pWL1 and pWL2 may have an etch selectivity equal to about 1, such that an etch rate of the mask insulating layer 202 is substantially equal to an etch rate of the first and second preliminary word lines pWL1 and pWL2. For example, the mask insulating layer 202 may have an etch selectivity of 0.95 to 1.05 with respect to the first and second preliminary word lines pWL1 and pWL2. The portion of the mask insulating layer 202 may be removed when the portion of the first preliminary word line pWL1 and the portion of the second preliminary word line pWL2 are removed.

In an embodiment, the portion of the mask insulating layer 202, the portion of the first preliminary word line pWL1, and the portion of the second preliminary word line pWL2 may be removed by an etch-back process.

Referring to FIG. 9C, a preliminary mold layer 203 may be formed. The preliminary mold layer 203 may be formed on the preliminary gate insulating layer pGO, the first word line WL1, the second word line WL2, and the mask pattern MP. The preliminary mold layer 203 may cover the exposed surface of the preliminary gate insulating layer pGO, the top surface of the mask pattern MP, the curved surface WL1_C of the first word line WL1, and the curved surface WL2_C of the second word line WL2.

Referring back to FIG. 5, the insulating structures 201, the preliminary mold layers 203, and the preliminary gate insulating layer pGO may be partially removed. As a result of the partial removal of the insulating structure 201, the insulating layer ILD may be formed. As a result of the partial removal of the preliminary mold layer 203, the mold layer MD may be formed. As a result of the partial removal of the preliminary gate insulating layer pGO, a plurality of gate insulating layers GO may be formed. Since the mold layer MD and the gate insulating layer GO are formed, the gate structure GST may be defined.

The first upper insulating layer UIL1 may be formed on the insulating layers ILD and the gate structures GST. A process may be performed to remove a portion of the first upper insulating layer UIL1. Next, the data contacts BC may be formed. The data contact BC may be formed to fill an empty space that is formed by removing a portion of the first upper insulating layer UIL1.

The second upper insulating layer UIL2 may be formed on the first upper insulating layer UIL1 and the data contact BC. A process may be performed to remove a portion of the second upper insulating layer UIL2. Next, the landing pads LP may be formed. Each of the landing pad LP may fill an empty space, which is formed by removing a portion of the second upper insulating layer UIL2. The data storage patterns DSP may be formed to be connected to the landing pads LP, respectively. The landing pads LP may generally have a planar upper surface having horizontal dimensions (e.g., in both the X and Y directions) that are both larger than wiring to which the landing pad LP is connected to facilitate connections thereto (e.g., to provide a larger surface to contact a later formed via). A horizontal wiring may be integrally formed with a landing pad LP (e.g., patterned out of the same metal layer) such that the wiring and pad have coplanar upper surfaces or a landing pad LP may be discretely formed such that it is not in contact with any wiring formed at its vertical level.

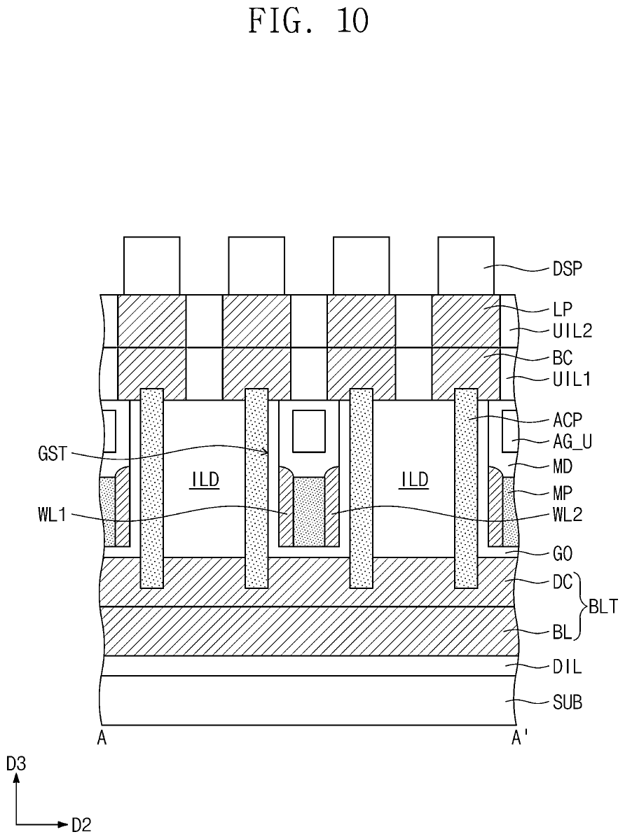

FIG. 10 is a sectional view illustrating a semiconductor device according to an embodiment of the inventive concept. The semiconductor device of FIG. 10 may be similar to the semiconductor device described with reference to FIGS. 4 to 8, except for the features to be described below.

Referring to FIG. 10, an upper air gap AG_U may be provided. It should be appreciated that an “air gap” may comprise a gap having air or other gases (e.g., such as those present during manufacturing) or may comprise a gap forming a vacuum therein. The upper air gap AG_U may be disposed in the mold layer MD. A surface of the upper air gap AG_U may be defined by the mold layer MD. The upper air gap AG_U may be overlapped with the mask pattern MP. The upper air gap AG_U may be spaced apart from the mask pattern MP and the first and second word lines WL1 and WL2. A bottom of the upper air gap AG_U may be higher than a top surface of the mask pattern MP, an uppermost portion of the first word line WL1, and an uppermost portion of the second word line WL2.

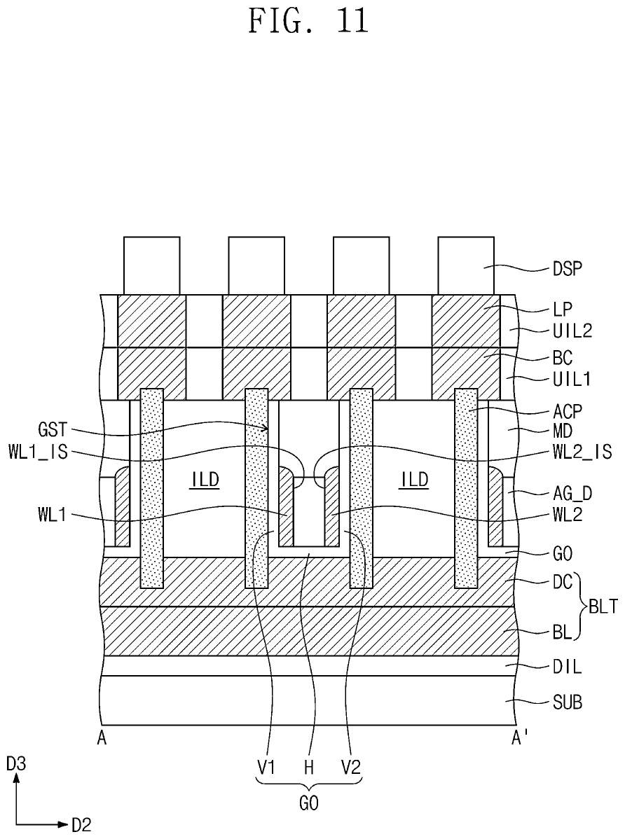

FIG. 11 is a sectional view illustrating a semiconductor device according to an embodiment of the inventive concept. The semiconductor device of FIG. 11 may be similar to the semiconductor device described with reference to FIGS. 4 to 8, except for distinctions described below.

Referring to FIG. 11, the semiconductor device may not include the mask pattern MP. A lower air gap AG_D may be provided in place of the mask pattern MP. The lower air gap AG_D may be disposed between the first and second word lines WL1 and WL2. The inner side surface WL1_IS of the first word line WL1, the inner side surface WL2_IS of the second word line WL2, and the top surface of the horizontal portion H of the gate insulating layer GO may be exposed to the lower air gap AG_D. A top surface of the lower air gap AG_D may be defined by the mold layer MD. A side surface of the lower air gap AG_D may be defined by the inner side surface WL1_IS of the first word line WL1 and the inner side surface WL2_IS of the second word line WL2. A bottom surface of the lower air gap AG_D may be defined by the top surface of the horizontal portion H of the gate insulating layer GO.

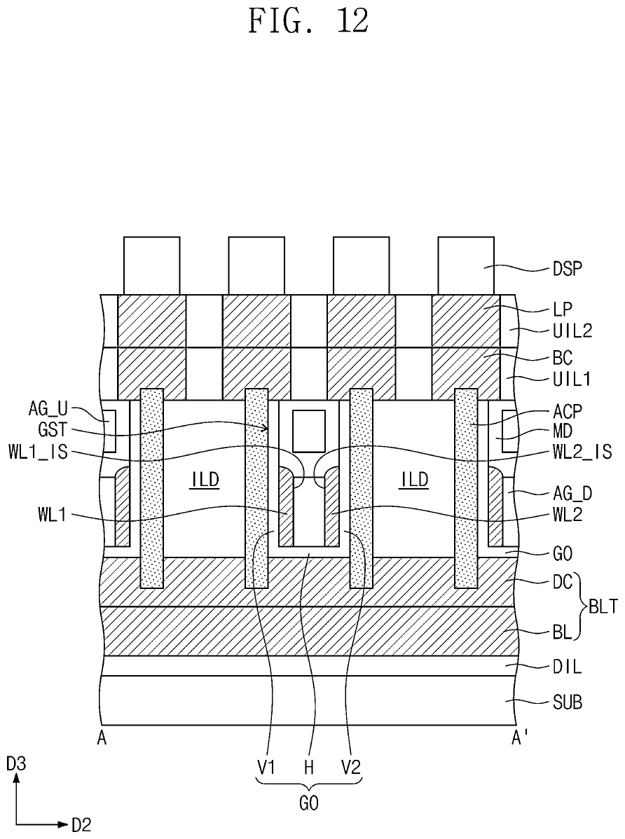

FIG. 12 is a sectional view illustrating a semiconductor device according to an embodiment of the inventive concept. The semiconductor device of FIG. 12 may be similar to the semiconductor device described with reference to FIGS. 4 to 8 and 11, except for distinctions described below.

Referring to FIG. 12, the semiconductor device may not include the mask pattern MP. In the present embodiment, the lower air gap AG_D and the upper air gap AG_U may be provided. The upper air gap AG_U may be overlapped with the lower air gap AG_D. The upper air gap AG_U may be spaced apart from the first word line WL1, the second word line WL2, and the lower air gap AG_D. The upper air gap AG_U may be situated above the lower air gap AG_D.

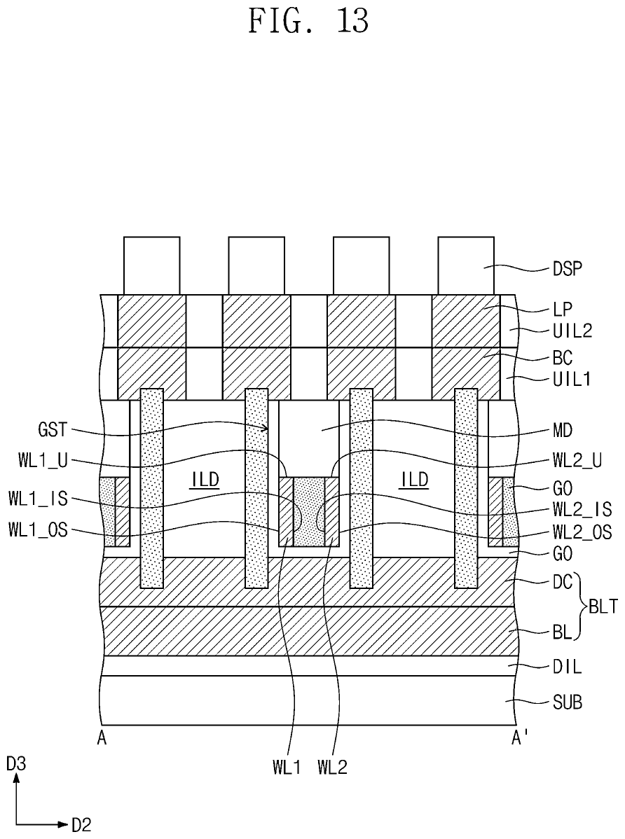

FIG. 13 is a sectional view illustrating a semiconductor device according to an embodiment of the inventive concept. The semiconductor device of FIG. 13 may be similar to the semiconductor device described with reference to FIGS. 4 to 8, except for the features to be described below.

Referring to FIG. 13, the first word line WL1 may include a top surface WL1_U, which is in contact with the mold layer MD. The top surface WL1_U of the first word line WL1 may connect the inner and outer side surfaces WL1_IS and WL1_OS of the first word line WL1 to each other. The top surface WL1_U of the first word line WL1 may be flat. The second word line WL2 may include a top surface WL2_U, which is in contact with the mold layer MD. The top surface WL2_U of the second word line WL2 may connect the inner and outer side surfaces WL2_IS and WL2_OS of the second word line WL2 to each other. The top surface WL2_U of the second word line WL2 may be flat. The top surface WL1_U of the first word line WL1, the top surface WL2_U of the second word line WL2, and the top surface of the mask pattern MP may be vertically even with each other. The top surface WL1_U of the first word line WL1, the top surface WL2_U of the second word line WL2, and the top surface of the mask pattern MP may be coplanar with each other.

According to an embodiment of the inventive concept, a semiconductor device may include a mask pattern that has an etch selectivity of substantially one with respect to a word line. Due to the mask pattern, it may be possible to increase a size of a space, which is filled with a mold layer. Thus, it may be possible to prevent a void or seam from being formed in a process of filling the mold layer and thereby to improve the electrical characteristics and reliability of the semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a bit line structure;
a gate insulating layer on the bit line structure;
a first word line and a second word line respectively on first and second inner side surfaces of the gate insulating layer;
a first channel layer and a second channel layer respectively in contact with first and second outer side surfaces of the gate insulating layer;
a mask pattern in contact with the first and second word lines; and
a mold layer in contact with a top surface of the mask pattern,
wherein the mask pattern comprises an insulating material, and
wherein a level of the top surface of the mask pattern is equal to or lower than a level of the uppermost portion of the first word line and a level of the uppermost portion of the second word line.

2. The semiconductor device of claim 1, wherein each of the first and second word lines comprises:
an outer side surface in contact with the gate insulating layer;
an inner side surface in contact with the mask pattern; and
a curved surface in contact with the mold layer.

3. The semiconductor device of claim 2, wherein the gate insulating layer comprises:
a first vertical portion between the first channel layer and the first word line;
a second vertical portion between the second channel layer and the second word line; and
a horizontal portion connecting the first vertical portion to the second vertical portion,
wherein, with respect to a vertical cross section, the horizontal portion has a top surface having a portion extending from the first vertical portion to the second vertical portion that is completely covered with the first word line, the second word line, and the mask pattern.

4. The semiconductor device of claim 3, wherein a bottom surface of the mask pattern is in contact with the top surface of the horizontal portion.

5. The semiconductor device of claim 1, wherein the mold layer comprises a first air gap formed therein.

6. The semiconductor device of claim 5, wherein a bottom of the first air gap is higher than the uppermost portion of the first word line and the uppermost portion of the second word line.

7. The semiconductor device of claim 5, wherein the first air gap overlaps the mask pattern with respect to a top down view.

8. The semiconductor device of claim 5, wherein the first air gap is spaced apart from the first and second word lines.

9. The semiconductor device of claim 1, wherein the mask pattern has an etch selectivity of 0.95 to 1.05 with respect to the first word line.

10. The semiconductor device of claim 1,
wherein the bit line structure comprises a bit line and a connection layer on the bit line, and
wherein the first channel layer and the second channel layer are electrically connected to the connection layer.

11. The semiconductor device of claim 1, wherein the mask pattern and the mold layer comprise different insulating materials from each other.

12. The semiconductor device of claim 1, wherein the top surface of the mask pattern is even with a top surface of the first word line.

13. The semiconductor device of claim 1, wherein a respective surface of each of the first and second word lines is completely covered with the gate insulating layer, the mask pattern, and the mold layer.

14. A semiconductor device, comprising:
a bit line structure;
a gate insulating layer on the bit line structure;
a first word line and a second word line respectively on first and second inner side surfaces of the gate insulating layer;
a first channel layer and a second channel layer respectively on first and second outer side surfaces of the gate insulating layer;
a mask pattern between the first and second word lines; and
a mold layer in contact with a top surface of the mask pattern,
wherein each of the first and second word lines comprises an outer side surface in contact with the gate insulating layer and an inner side surface opposite to the outer side surface,
wherein the mask pattern comprises an insulating material, and
wherein a level of a top surface of the first channel layer is higher than a level of a top surface of the mask pattern.

15. The semiconductor device of claim 14, wherein a side surface of the mask pattern is in contact with the inner side surface of the first word line.

16. The semiconductor device of claim 14, wherein the mask pattern comprises a nitride material that has an etch selectivity of 0.95 to 1.05 with respect to the first word line.

17. The semiconductor device of claim 14, wherein the top surface of the mask pattern is coplanar with a top surface of the first word line.

18. The semiconductor device of claim 14, wherein the mask pattern covers the inner side surface of the first word line and the inner side surface of the second word line.

19. A semiconductor device, comprising:
a bit line structure;
a gate structure on the bit line structure;
a first channel layer and a second channel layer spaced apart from each other with the gate structure interposed therebetween;
first and second landing pads respectively on the first and second channel layers; and
first and second data storage patterns respectively connected to the first and second landing pads,
wherein the gate structure comprises:
a gate insulating layer on the bit line structure;
a first word line and a second word line on the gate insulating layer;
a mask pattern between the first and second word lines; and
a mold layer in contact with a top surface of the mask pattern,
wherein the mask pattern and the mold layer are formed of insulating materials that are different from each other, and
wherein a level of the top surface of the mask pattern is lower than a level of the uppermost portion of the first word line.

20. The semiconductor device of claim 19, further comprising a first data contact connecting the first channel layer to the first landing pad.
